(19) United States
(12) Patent Application Publication
(10) Pub. No.: US 2006/0198412 A1
(43) Pub. Date: Sep. 7, 2006

(54) Grating-coupled surface emitting laser with gallium arsenide substrate

(76) Inventor: Ralph H. Johnson, Murphy, TX (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 11/369,716

(22) Filed: Mar. 7, 2006

Related U.S. Application Data
(60) Provisional application No. 60/659,246, filed on Mar. 7, 2005.

(51) Int. Cl. H01S 5/00; H01S 3/08

(52) U.S. Cl. 372/45.012; 372/102

(57) ABSTRACT

This disclosure concerns grating-coupled surface emitting (GSE) lasers with Gallium Arsenide (GaAs) substrates. In one example, a GSE laser includes a GaAs substrate, a lower cladding layer disposed on the substrate, a Dilute Nitride active region disposed on the lower cladding layer, and an upper cladding layer disposed on the active region.

### CROSS-REFERENCE TO RELATED APPLICATIONS

This application claims the benefit of U.S. Provisional Patent Application No. 60/659,246 titled “Grating-Coupled Surface Emitting Laser on Gallium Arsenide Substrate with Dilute Nitride Active Regions” filed Mar. 7, 2005, which is hereby incorporated in its entirety by this reference.

### BACKGROUND OF THE INVENTION

1. The Field of the Invention

The invention generally relates to grating-coupled surface emitting (GSE) lasers. More specifically, the invention relates to GSE lasers with Gallium Arsenide (GaAs) substrates.

2. Description of the Related Art

Electronic circuitry is increasingly integrated into data communication and data processing devices. For example, integrated circuits, often referred to as microchips or simply chips, are used in a variety of applications, such as high speed optical networks. One type of chip, the laser diode chip, plays an increasingly important role in today's high speed optical networks. Laser diode chips are complex semiconductors that convert an electrical current into light. A laser diode chip, also known simply as a laser, is an essential component of a transmitter optical sub assembly (TOSA). A TOSA is often paired with a receiver optical sub assembly (ROSA) in an optoelectronic transceiver.

Examples of lasers that can be integrated into TOSAs include edge emitting lasers, vertical cavity surface emitting lasers (VCSELs) and grating-coupled surface emitting (GSE) lasers. VCSELs and GSE lasers have advantages over edge emitting lasers inasmuch as VCSELs and GSE lasers can be tested at the wafer level without the need to separate individual lasers from the wafer and can be designed with a beam for better coupling to a fiber optic cable. GSE lasers also have advantages over VCSELs because, for example, GSE lasers have a higher output power than VCSELs. GSE lasers, therefore, have certain advantages over both edge emitting lasers as well as VCSELs.

One problem with current GSE lasers, however, is a high cost of production due to the use of Indium Phosphide (InP) semiconductor technology. The use of InP semiconductor technology in GSE lasers involves forming the substrates of the GSE lasers out of InP. InP substrates tend to be very fragile and tend to break very easily. A high rate of breakage results in a low yield of usable lasers. Low yield rates increase the average cost of producing a GSE laser.

### BRIEF SUMMARY OF SOME EXAMPLE EMBODIMENTS OF THE INVENTION

Example embodiments of the present invention relate to grating-coupled surface emitting (GSE) lasers with Gallium Arsenide (GaAs) substrates.

In one example, a GSE laser includes a GaAs substrate, a lower cladding layer disposed on the substrate, a Dilute Nitride active region disposed on the lower cladding layer, and an upper cladding layer disposed on the active region.

In another example, a transmitter optical sub assembly includes a GSE laser. In this example, the GSE laser also includes a GaAs substrate, a lower cladding layer disposed on the substrate, a Dilute Nitride active region disposed on the lower cladding layer, and an upper cladding layer disposed on the active region.

In yet another example, an optoelectronic transceiver includes a housing, a receiver optical sub assembly (ROSA) disposed within the housing, and a transmitter optical sub assembly (TOSA) disposed within the housing. In this example, the TOSA also includes a GSE laser. In this example, the GSE laser includes a GaAs substrate, a lower cladding layer disposed on the substrate, a Dilute Nitride active region disposed on the lower cladding layer, and an upper cladding layer disposed on the active region.

These and other aspects of the present invention will become more fully apparent from the following description and appended claims.

### BRIEF DESCRIPTION OF THE DRAWINGS

To further clarify certain aspects of the present invention, a more particular description of the invention will be rendered by reference to specific embodiments thereof which are illustrated in the appended drawings. It is appreciated that these drawings depict only example embodiments of the invention and are therefore not to be considered limiting of its scope. Aspects of the invention will be described and explained with additional specificity and detail through the use of the accompanying drawings in which:

FIG. 1 illustrates an exemplary optoelectronic transceiver;

FIG. 2 illustrates the epitaxial structure of an example grating-coupled surface emitting (GSE) laser; and

FIG. 3 illustrates an energy band gap diagram associated with the GSE laser of FIG. 2.

### DETAILED DESCRIPTION OF SOME EXEMPLARY EMBODIMENTS

Example embodiments relate to grating-coupled surface emitting (GSE) lasers that are produced with Gallium Arsenide (GaAs) substrates. Reference will now be made to the drawings which disclose various aspects of exemplary embodiments of the invention. It is to be understood that the drawings are diagrammatic and schematic representations of such exemplary embodiments, and are not limiting of the present invention, nor are they necessarily drawn to scale.

I. Example Optoelectronic Transceiver

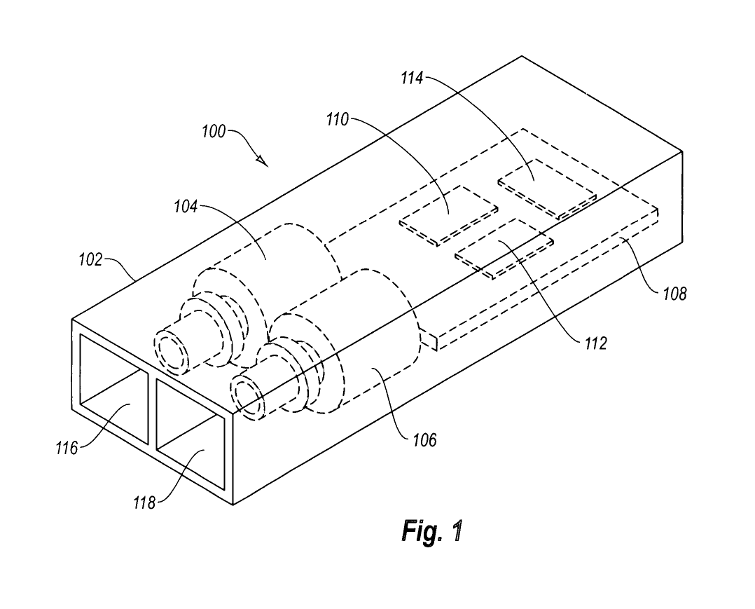

Turning now to FIG. 1, an exemplary optoelectronic transceiver 100 is illustrated. Optoelectronic transceiver 100 functions to convert optical signals into electrical signal and electrical signals into optical signals. Optoelectronic transceiver 100 includes a housing 102. Optoelectronic transceiver 100 also includes transmitter optical sub assembly (TOSA) 104 disposed within housing 102. Optoelectronic transceiver 100 further includes a receiver optical sub assembly (ROSA) 106 disposed within housing 102. TOSA 104 includes a housing and an optical transmitter, such as a GSE laser (not shown), disposed within the TOSA housing. ROSA 106 includes a housing and an optical receiver, such as a photodiode (not shown), disposed within the ROSA housing. Optoelectronic transceiver 100 also includes a printed circuit board PCB) 108 disposed within housing 102. PCB 108 includes circuitry that is used in the operation of TOSA 104 and ROSA 106, including a laser driver 110, a post amplifier 112, and a microprocessor 114 to control the functions of the laser driver and the post amplifier. Optoelectronic transceiver 100 also includes a transmit port 116 through which optical signals are transmitted and a receive port 118 through which optical signals are received.

Where optoelectronic transceiver 100 includes a TOSA with a laser such as one of the exemplary GSE lasers disclosed herein, optoelectronic transceiver 100 can achieve data rates of, for example, 10.7 Gb/s or higher. Additionally, optoelectronic transceiver 100 can support transmission standards such as, for example, Optical Gigabit Ethernet, 1x Fiber Channel, 2x Fiber Channel, OC-3/STM-1, OC-12/STM-4, and OC-48/STM-16. Moreover, example embodiments of optoelectronic transceiver 100 conform to various MSAs such as, for example, SFP, SFF, GBIC, and XFP.

Optoelectronic transceiver 100 is not limited to the exact components illustrated in FIG. 1, and could include additional or alternative components. For example, where the functionality provided by the circuitry of PCB 108 is available to optoelectronic transceiver 100 from a source external to optoelectronic transceiver 100, an alternative embodiment of optoelectronic transceiver 100 includes housing 102, TOSA 104, and ROSA 106. Likewise, optoelectronic transceiver 100 is not limited to the housing configuration or TOSA or ROSA configuration depicted in FIG. 1, and could be implemented in various other configurations.

II. Example GSE Laser Epitaxial Structure

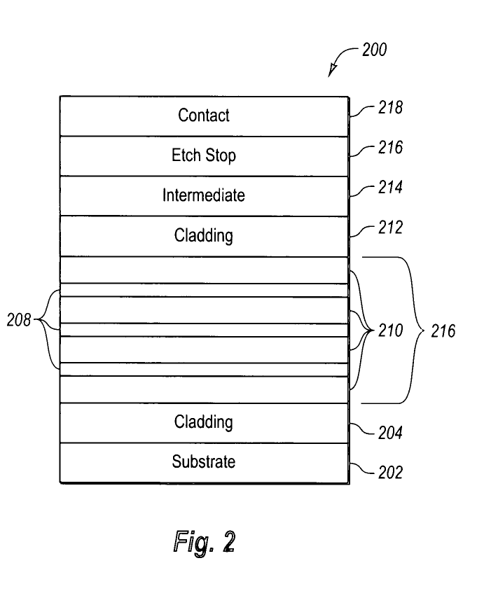

Turning now to FIG. 2, the epitaxial structure of an example GSE laser 200 is illustrated. In the example disclosed in FIG. 2, GSE laser 200 includes a substrate 202. Disposed on substrate 202 is a lower cladding layer 204. Disposed on lower cladding layer 204 is an active region 206. Active region 206 is made up of quantum well layers 208 that are interleaved with barrier layers 210. Disposed on active region 206 is an upper cladding layer 212. Disposed on upper cladding layer 212 is an optional intermediate layer 214. Disposed on intermediate layer 214 is an etch stop layer 216. Disposed on etch stop layer 216 is a contact layer 218.

III. Example GSE Laser Energy Band Gap

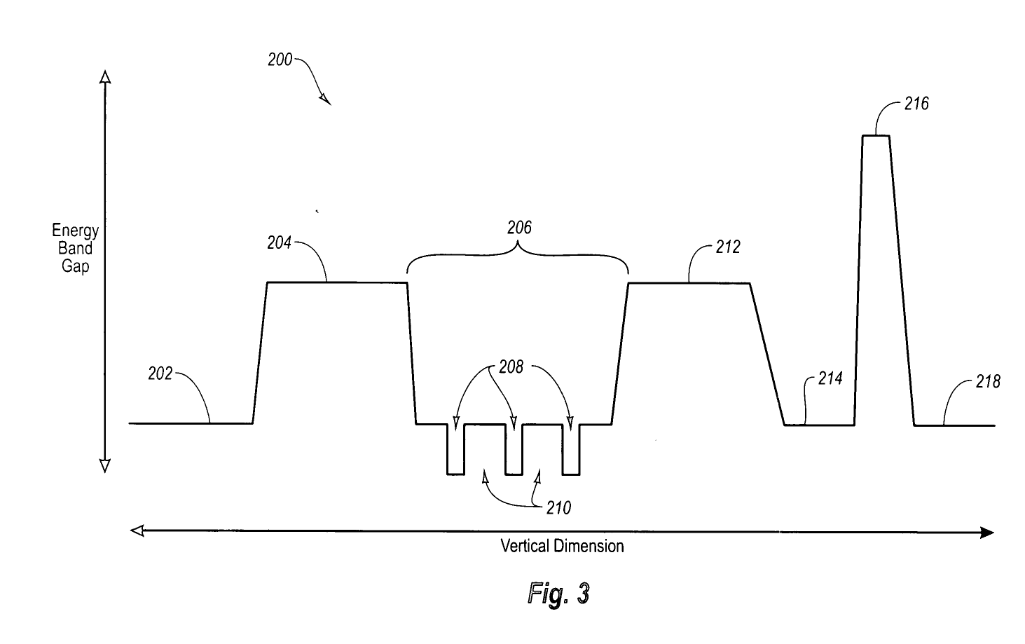

Turning now to FIG. 3, an energy band gap diagram of the GSE laser 200 of FIG. 2 is illustrated. The horizontal axis of FIG. 3 illustrates the relative vertical dimension of each layer of GSE laser 200. The vertical axis of the diagram of FIG. 3 illustrates the relative energy band gap of each layer of GSE laser 200. The diagram of FIG. 3 is not necessarily drawn to scale. The discussion in connection with FIG. 3 will give more detail about each layer of GSE laser 200, aspects of which are disclosed in both FIG. 2 and FIG. 3. All quantities of elements disclosed herein are to be understood in terms of atomic percentages. For example, if two element quantities “x” and “y” have the relationship of x+y=1.0, it should be understood that the value of the atomic percent of the element corresponding to “x” plus the value of the atomic percent of the element corresponding to “y” add up to about 100 atomic percent.

As discussed above in connection with FIG. 2, GSE laser 200 includes substrate 202. Substrate 202 is formed from GaAs. Intermediate layer 214 and contact layer 218 are also both formed from GaAs. Lower cladding layer 204 and upper cladding layer 212 are both formed from AlₐGa_{b}, where a+b=1.0 and in one example embodiment the value of “a” is about 0.7 and the value of “b” is about 0.3. In various example embodiments, lower cladding layer 204 and upper cladding layer 212 range in thickness from about 0.2 microns to about 1.0 microns. In one example embodiment, lower cladding layer 204 and upper cladding layer 212 are each about 0.4 microns thick. Etch stop layer 216 is formed from AlₕGaᵢAs_{1.0}, where h+i=1 and in various example embodiments “h” has a range from about 0.5 to about 1.0 and “i” has a range from about 0 to about 0.5.

Substrate 202 can either be an N-type substrate or a P-type substrate. Likewise, lower cladding layer 204 and upper cladding layer 212 can each be either an N-type cladding layer or a P-Type cladding layer. Where substrate 202 is an N-type substrate, lower cladding layer 204 is an N-type cladding layer and upper cladding layer 212 is a P-type cladding layer. Conversely, where substrate 202 is a P-type substrate, lower cladding layer 204 is a P-type cladding layer and upper cladding layer 212 is an N-type cladding layer.

Active region 206 is positioned between lower cladding layer 204 and upper cladding layer 212. Each quantum well layer 208 of active region 206 is substantially comprised of Dilute Nitride. As used herein, the term “Dilute Nitride” refers to a substance having a chemical formula of In_{c}Ga_{d}AsₑN_{f}(Sb_{g}), where c+d=1.0 and e+f+g=1.0. As used herein, the term “Dilute Nitride active region” refers to an active region that is at least partially comprised of Dilute Nitride.

In one example, where GSE laser 200 is designed to operate with an emission wavelength of 1.3 microns, “c” can have a range from about 0.25 to about 0.32, “d” can have a range from about 0.68 to about 0.75, “e” can have a range from about 0.932 to about 0.985, “f” can have a range from about 0.015 to about 0.028, and “g” can have a range from about 0.00 to about 0.04. An example 1.3 micron GSE laser 200 can have an active region 206 with quantum well layers 208 formed from a substance having a chemical formula of about In_{0.27}Ga_{0.77}As_{0.965}N_{0.02}(Sb_{0.015}). In another example, where GSE laser 200 is designed to operates with an emission wavelength of 1.5 microns, “c” can have a range from about 0.25 to about 0.5, “d” can have a range from about 0.5 to about 0.75, “e” can have a range from about 0.88 to about 0.985, “f” can have a range from about 0.015 to about 0.04, and “g” can have a range from about 0.00 to about 0.08. Various other example embodiments of GSE laser 200 can be designed to operate with an emission wavelength of about 1260 nm to about 1370 nm or about 1450 nm to about 1650 nm, or other wavelength, depending on the output requirements for GSE laser 200.

Quantum well layers 208 of active region 206 are interleaved with barrier layers 210 which are formed from GaAs. In some example embodiments of GSE laser 200, each quantum well layer 208 ranges in thickness from about 35 angstroms to about 80 angstroms. In other example embodiments of GSE laser 200, each quantum well layer 208 ranges in thickness from about 50 angstroms to about 70 angstroms. In some example embodiments of GSE laser 200, each barrier layer 210 can range in thickness from about 100 angstroms to about 200 angstroms. In some example embodiments of GSE laser 200, the total thickness of active region 206 is about 2000 angstroms, although other thicknesses are possible depending on the output requirements for GSE laser 200.

Producing GSE lasers with GaAs substrates is less expensive on average than producing GSE lasers with InP substrates because GaAs substrates tend to be less fragile and less prone to breakage than InP substrates. GSE lasers with GaAs substrates and Dilute Nitride active regions are also more easily produced than InGaAsN/GaAs based VCSELs. InGaAsN/GaAs based VCSELs use carriers, electrons and holes, which are directly in the path of the optical standing wave of the laser cavity, to provide current to quantum wells. These carriers tend to absorb some of the light produced by the VCSELs, a problem known as “free carrier absorption,” which limits the power output of the VCSELs and makes the VCSELs inadequate for some applications. The differences in the geometry of the active region between InGaAsN/GaAs based VCSELs and the example GSE lasers disclosed herein results in improved operational characteristics in the example GSE lasers.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed is:

1. A grating-coupled surface emitting (GSE) laser comprising:
a Gallium Arsenide (GaAs) substrate;
a lower cladding layer disposed on the substrate;
a Dilute Nitride active region disposed on the lower cladding layer; and
an upper cladding layer disposed on the active region.

2. The GSE laser as recited in claim 1, wherein the lower cladding layer and the upper cladding layer each range in thickness from about 0.2 microns to about 1.0 microns.

3. The GSE laser as recited in claim 1, wherein the lower cladding layer and the upper cladding layer each comprise about 30 group III atomic percent Aluminum and about 70 group III atomic percent Gallium.

4. The GSE laser as recited in claim 1, wherein the active region comprises Dilute Nitride quantum well layers interleaved with barrier layers.

5. The GSE laser as recited in claim 4, wherein each barrier layer comprises GaAs.

6. The GSE laser as recited in claim 4, wherein each of the quantum well layers ranges in thickness from about 35 angstroms to about 80 angstroms.

7. The GSE laser as recited in claim 4, wherein each barrier layer ranges in thickness from about 100 angstroms to about 200 angstroms.

8. The GSE laser as recited in claim 1, further comprising:
an AlGaAs etch stop layer disposed on the upper cladding layer; and
a GaAs contact layer disposed on the etch stop layer.

9. The GSE laser as recited in claim 8, wherein the etch stop layer comprises about 50 group III atomic percent to about 100 group III atomic percent Aluminum.

10. The GSE laser as recited in claim 1, wherein the GSE laser operates with an emission wavelength of about 1260 nm to about 1370 mm.

11. The GSE laser as recited in claim 1, wherein the GSE laser operates with an emission wavelength of about 1450 nm to about 1650 mm.

12. The GSE laser as recited in claim 1, wherein the substrate is an N-type substrate, the lower cladding layer is an N-type cladding layer, and the upper cladding layer is a P-type cladding layer.

13. A transmitter optical sub assembly (TOSA) comprising:
a housing; and
a grating-coupled surface emitting (GSE) laser disposed within the housing, the GSE laser comprising:
a Gallium Arsenide (GaAs) substrate;
a lower cladding layer disposed on the substrate;
a Dilute Nitride active region disposed on the lower cladding layer; and
an upper cladding layer disposed on the active region.

14. The TOSA as recited in claim 13, wherein the active region comprises Dilute Nitride quantum well layers interleaved with GaAs barrier layers.

15. The TOSA as recited in claim 13, further comprising:
an AlGaAs etch stop layer disposed on the upper cladding layer; and
a GaAs contact layer disposed on the etch stop layer.

16. The TOSA as recited in claim 15, wherein the etch stop layer comprises about 0 group III atomic percent to about 50 group III atomic percent Gallium.

17. The TOSA as recited in claim 13, wherein the TOSA operates with an emission wavelength of about 1260 nm to about 1370 nm.

18. The TOSA as recited in claim 13, wherein the TOSA operates with an emission wavelength of about 1450 nm to about 1650 nm.

19. The TOSA as recited in claim 13, wherein the substrate is an N-type substrate, the lower cladding layer is an N-type cladding layer, and the upper cladding layer is a P-type cladding layer.

20. An optoelectronic transceiver comprising:
a housing;
a receiver optical sub assembly (ROSA) disposed within the housing; and
a transmitter optical sub assembly (TOSA) disposed within the housing, the TOSA comprising:
a TOSA housing; and
a grating-coupled surface emitting (GSE) laser disposed within the TOSA housing, the GSE laser comprising:
a Gallium Arsenide (GaAs) substrate;
a lower cladding layer disposed on the substrate;
a Dilute Nitride active region disposed on the lower cladding layer; and
an upper cladding layer disposed on the active region.

21. The optoelectronic transceiver as recited in claim 20, wherein the lower cladding layer and the upper cladding layer each range in thickness from about 0.2 microns to about 1.0 microns and each comprise about 30 group III atomic percent Aluminum and about 70 group III atomic percent Gallium.

22. The optoelectronic transceiver as recited in claim 20, wherein the active region comprises quantum well layers interleaved with barrier layers.

23. The optoelectronic transceiver as recited in claim 20, further comprising:
an AlGaAs etch stop layer disposed on the upper cladding layer; and
a GaAs contact layer disposed on the etch stop layer.

24. The optoelectronic transceiver as recited in claim 23, wherein the etch stop layer comprises about 50 group III atomic percent to about 100 group III atomic percent Aluminum.

25. The optoelectronic transceiver as recited in claim 20, wherein the optoelectronic transceiver is compatible with a data rate of about 10.7 Gb/s or higher.

26. The optoelectronic transceiver as recited in claim 20, wherein the optoelectronic transceiver supports one or more of Optical Gigabit Ethernet, 1x Fiber Channel, 2x Fiber Channel, OC-3/STM-1, OC-12/STM-4, or OC-48/STM-16.

27. The optoelectronic transceiver as recited in claim 20, wherein the optoelectronic transceiver substantially conforms to one or more of the SFP, SFF, GBIC, or XFP MSAs.

28. The optoelectronic transceiver as recited in claim 20, wherein the optoelectronic transceiver operates with an emission wavelength of about 1260 nm to about 1370 nm.

29. The optoelectronic transceiver as recited in claim 20, wherein the optoelectronic transceiver operates with an emission wavelength of about 1450 nm to about 1650 nm.

30. The optoelectronic transceiver as recited in claim 20, wherein the substrate is an N-type substrate, the lower cladding layer is an N-type cladding layer, and the upper cladding layer is a P-type cladding layer.

31. An optoelectronic transceiver comprising:
a housing;
a receiver optical sub assembly (ROSA) disposed within the housing; and
a transmitter optical sub assembly (TOSA) disposed within the housing, the TOSA comprising:
a TOSA housing; and
a grating-coupled surface emitting (GSE) laser disposed within the TOSA housing, the GSE laser comprising:
a Gallium Arsenide (GaAs) substrate;
a lower cladding layer disposed on the substrate;
an active region disposed on the lower cladding layer; and
an upper cladding layer disposed on the active region,
wherein the GSE laser operates with an emission wavelength of about 1260 nm to about 1370 nm or about 1450 nm to about 1650 nm.

32. The optoelectronic transceiver as recited in claim 31, wherein the active region comprises Dilute Nitride.
